(19) United States
(12) Patent Application Publication
(10) Pub. No.: US 2008/0038872 A1
(43) Pub. Date: Feb. 14, 2008

(54) Method of manufacturing semiconductor device

(75) Inventor: Naoto Kimura, Fukuoka (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kanagawa (JP)

(21) Appl. No.: 11/882,845

(22) Filed: Aug. 6, 2007

(30) Foreign Application Priority Data
Aug. 8, 2006 (JP) 215677/2006

(51) Int. Cl. H01L 21/00

(52) U.S. Cl. 438/109; 257/E23.003

(57) ABSTRACT

Provided are a semiconductor device capable of mounting a plurality of semiconductor chips in compact on a leadframe and reducing manufacturing costs, and a method of manufacturing the same. The semiconductor device includes: a semiconductor chip (20) having a top surface (20a) provided with a plurality of electrode pads (22) on a periphery thereof, and an under surface (20b) which is opposite to the top surface, the semiconductor chip (20) being mounted with a side of the top surface (20a) being opposed to an under surface (3b) of the island portion (3); a semiconductor chip (10) having a top surface (10a) provided with a plurality of electrode pads (12) on a periphery thereof, and an under surface (10b) which is opposite side to the top surface, the semiconductor chip (10) being mounted with a side of the under surface (10b) being opposed to a top surface (3a) of the island portion (3); a plurality of wires (30) each connecting an associated one of leads (5) and an associated one of electrode pads (12, 22) by reverse bonding, with a point on each lead (5) being a starting point, and with each electrode pad (12, 22) of one of the corresponding semiconductor chips (10, 20) being an ending point; and an encapsulation resin (40), in which the wires (30) are connected such that each side surface of the wires (30) contacts each electrode pad substantially in parallel with each top surface (10a, 20a) of the semiconductor chips (10, 20).

### BACKGROUND OF THE INVENTION

1. Field of the Invention

The present invention relates to a semiconductor device and a method of manufacturing the same, and more particularly, to a semiconductor device having a plurality of semiconductor chips laminated on a leadframe, and a method of manufacturing the same.

2. Description of the Related Art

As an example of a conventional semiconductor device, there is a semiconductor device as disclosed in JP 05-152503 A. FIG. 9 shows the semiconductor device disclosed in JP 05-152503 A. In the semiconductor device, long leads and short leads are alternately arranged and two semiconductor chips are mounted on both surfaces of a leadframe. As a result, a wire which is first bonded to an inner lead terminal of one of a long terminal and a short terminal is prevented from being deformed, thereby making it possible to wire-bond the inner lead terminal of the other of the long terminal and the short terminal, to the semiconductor chip.

FIG. 10 shows a conventional semiconductor device disclosed in JP 2003-347504 A. In the semiconductor device, a first LSI chip is mounted on an island, and a second LSI chip is mounted thereon via a spacer. Each electrode of the LSI chips is normally bonded to an inner lead of a leadframe.

As a conventional semiconductor device having a plurality of semiconductor chips mounted thereon, there is a semiconductor device as shown in FIG. 11. In the semiconductor device, a first semiconductor chip is mounted on an island portion of a leadframe, and a second semiconductor chip which is smaller than the first semiconductor chip, is mounted thereon.

Further, a semiconductor device disclosed in JP 11-097476 A (JP 2954109 B) is filed by the applicant of this application. According to the semiconductor device, in a ball-grid-array (BGA) type chip size package (CSP) semiconductor device having a chip-on-lead (COL) structure, leads and pads are connected to each other through wires by reverse bonding, with a point on each lead in the vicinity of the chip being a starting point and with each electrode pad on the chip being an ending point. As a result, it is possible to reduce a lead length and a package size.

However, the prior arts disclosed in the above-mentioned cited references have a room for improvement in the following points.

First, when each electrode of the chips is normally bonded to the leads, the wires extending from the electrodes of the semiconductor chips each rise substantially vertically with respect to each surface of the chips, and each form a loop shape. As a result, in any case of FIGS. 9 to 11, a space occupied by the wire portions is increased.

Second, in a case where a plurality of chips are laminated, as shown in FIG. 11, it is necessary to set the size of the chip disposed below to be larger than that of the chip disposed above so as to obtain a wider bonding area.

Third, in a case of FIG. 10, it is necessary to provide a spacer made of silicon or other materials in order to secure a gap between the two chips so that the wires extending from the first chip does not contact an under surface of the second chip, which results in increase in an entire thickness of the semiconductor device. In addition, material costs for the spacer and a process for mounting the spacer are required, which raises the manufacturing costs.

### SUMMARY

The present invention has been made to solve the above-mentioned problems, and it is an object of the present invention to provide a semiconductor device capable of mounting a plurality of semiconductor chips in compact on a leadframe and reducing manufacturing costs, and a method of manufacturing the same.

According to the present invention, there is provided a semiconductor device including: a leadframe including an island portion and a plurality of leads; a first semiconductor chip having a top surface provided with a plurality of electrode pads on a periphery thereof, and an under surface opposite to the top surface, the first semiconductor chip being mounted onto the under surface of the island portion of the leadframe so that the top surface of the first semiconductor chip opposes the under surface of the island portion of the leadframe; a second semiconductor chip having a top surface provided with a plurality of electrode pads on a periphery thereof, and an under surface opposite to the top surface, the second semiconductor chip being mounted onto the top surface of the island portion of the leadframe so that the under surface of the second semiconductor chip opposes the top surface of the island portion of the leadframe; a plurality of wires each connecting an associated one of the leads and an associated one of the electrode pads by reverse bonding, with a point on each lead of the plurality of leads of the leadframe being a starting point, and with each electrode pad of one of the corresponding first semiconductor chip and second semiconductor chip being an ending point; and an encapsulation resin for encapsulating the first semiconductor chip and the second semiconductor chip, in which the plurality of wires are connected so that each side surface of the plurality of wires contacts one of the electrode pads substantially in parallel with the each top surface of the first semiconductor chip and the second semiconductor chip.

According to the present invention, it is possible to mount a plurality of semiconductor chips in compact on a leadframe and reduce manufacturing costs.

According to the present invention, there is provided a method of manufacturing a semiconductor device, including the steps of: preparing a leadframe including an island portion and a plurality of leads; mounting a first semiconductor chip having a top surface provided with a plurality of electrode pads on a periphery thereof, and an under surface provided on an opposite side of the top surface, with a side of the top surface being opposed to an under surface of the island portion of the leadframe; mounting a second semiconductor chip having a top surface provided with a plurality of electrode pads on a periphery thereof, and an under surface provided on an opposite side of the top surface, with a side of the under surface being opposed to a top surface of the island portion of the leadframe; connecting wires to each an associated one of the leads and an associated one of the electrode pads by reverse bonding, with a point on each lead of the plurality of leads of the leadframe being a starting point, and with each electrode pad of one of the corresponding first semiconductor chip and second semiconductor chip being an ending point; and encapsulating the first semiconductor chip and the second semiconductor chip with an encapsulation resin, in which the wires are connected such that each side surface of the wires contacts one of the electrode pads substantially in parallel with each top surface of the first semiconductor chip and the second semiconductor chip.

According to the present invention, it is possible to mount a plurality of semiconductor chips in compact on a leadframe, and reduce manufacturing costs.

According to the present invention, it is possible to provide a semiconductor device capable of mounting a plurality of semiconductor chips in compact on a leadframe and reducing manufacturing costs, and a method of manufacturing the same.

### BRIEF DESCRIPTION OF THE DRAWINGS

In the accompanying drawings:

FIG. 1 is a cross-sectional diagram schematically showing a semiconductor device according to an embodiment of the present invention;

FIG. 2 is a cross-sectional diagram schematically showing a leadframe of the semiconductor device shown in FIG. 1;

FIG. 3 is a diagram for explaining a mounting process for a second semiconductor chip of the semiconductor device shown in FIG. 1;

FIG. 4 is a diagram for explaining a wire bonding process for the second semiconductor chip of the semiconductor device shown in FIG. 1;

FIG. 5 is a diagram for explaining a mounting process for a first semiconductor chip of the semiconductor device shown in FIG. 1;

FIG. 6 is a diagram for explaining a wire bonding process for the first semiconductor chip of the semiconductor device shown in FIG. 1;

FIG. 7 is a diagram for explaining a resin encapsulating process for the semiconductor device shown in FIG. 1;

FIGS. 8A and 8B are explanatory diagrams for comparing reverse wire bonding for the semiconductor device shown in FIG. 1 with normal bonding therefor;

FIG. 9 is a cross-sectional diagram of a conventional semiconductor device;

FIG. 10 is a cross-sectional diagram of the conventional semiconductor device; and

FIG. 11 is a cross-sectional diagram of the conventional semiconductor device.

### DETAILED DESCRIPTION OF THE PREFERRED EMBODIMENTS

Hereinafter, embodiments of the present invention will be described with reference to the drawings. It should be noted that in each figure, the same components are denoted by the same reference numerals and appropriate explanations thereof will be omitted. In addition, in each figure described below, structures of portions that are not related to essential parts of the present invention are omitted.

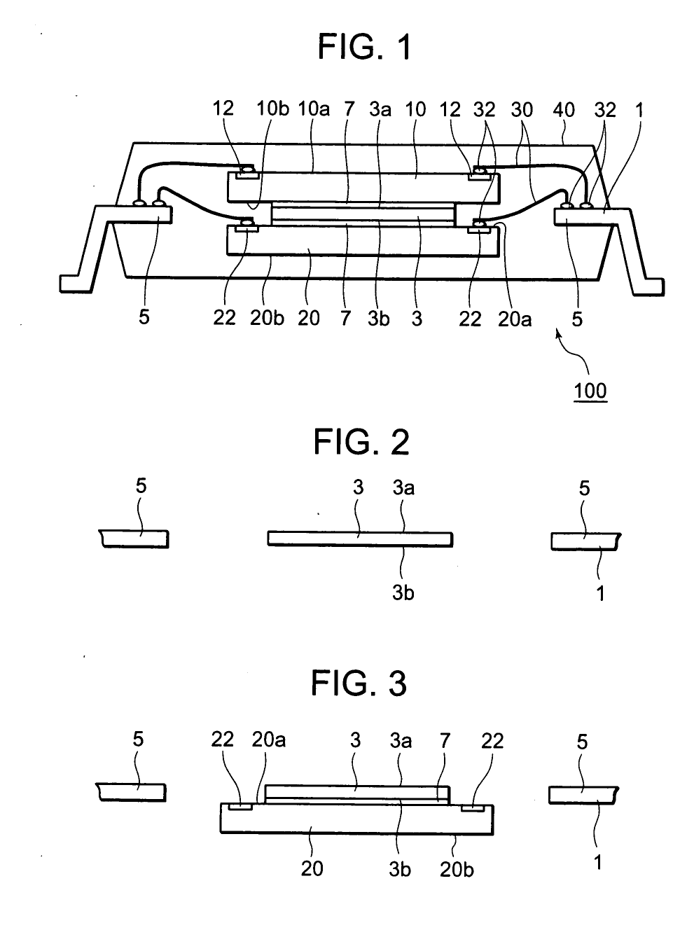

FIG. 1 is a cross-sectional diagram schematically showing a semiconductor device according to the embodiment of the present invention. A semiconductor device 100 according to this embodiment includes: a leadframe 1 including an island portion 3 and a plurality of leads 5; a first semiconductor chip 20 which has a top surface 20a provided with a plurality of electrode pads 22 on a periphery thereof, and an under surface 20b provided on an opposite side of the top surface 20a, and which is mounted with a side of the top surface 20a being opposed to an under surface 3b of the island portion 3 of the leadframe 1; a second semiconductor chip 10 which has a top surface 10a provided with a plurality of electrode pads 12 on a periphery thereof, and an under surface 10b provided on a side opposite to the top surface 10a, and which is mounted with a side of the under surface 10b being opposed to a top surface 3a of the island portion 3 of the leadframe 1; a plurality of wires 30 each connecting an associated one of the lead and associated one of the electrode pads by reverse bonding, with a point on each lead 5 of the plurality of leads 5 of the leadframe 1 being a starting point, and with electrode pads 22 and 12 of one of the corresponding first semiconductor chip 20 and second semiconductor chip 10 being an ending point; and an encapsulation resin 40 for encapsulating the first semiconductor chip 20 and the second semiconductor chip 10. The wires 30 are connected such that each side surface of the wires 30 contacts one of the electrode pads substantially in parallel with each of the top surfaces 10a and 20a of the first semiconductor chip 20 and the second semiconductor chip 10.

The under surface 3b of the island portion 3 has a size smaller than the dimension of the first semiconductor chip 20 excluding the electrode pads 22 thereof, the first semiconductor chip 20 being mounted under the island portion 3. The island portion 3 of the leadframe 1 may have a thickness of about less than 80 μm to 25 μm. In this embodiment, the thickness of the island portion 3 is set to 75 μm. In addition, in this embodiment, the first semiconductor chip 20 and the second semiconductor chip 10 have the same shape.

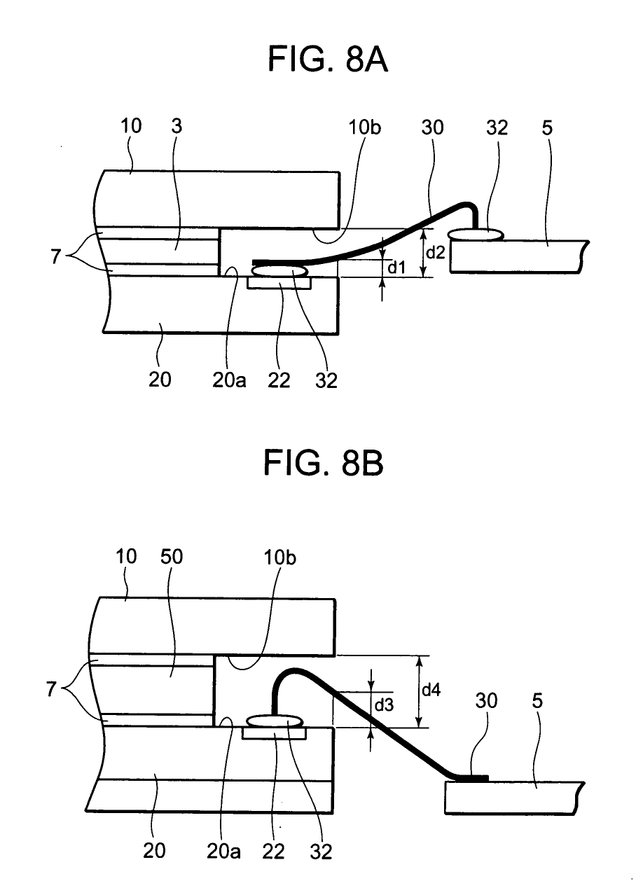

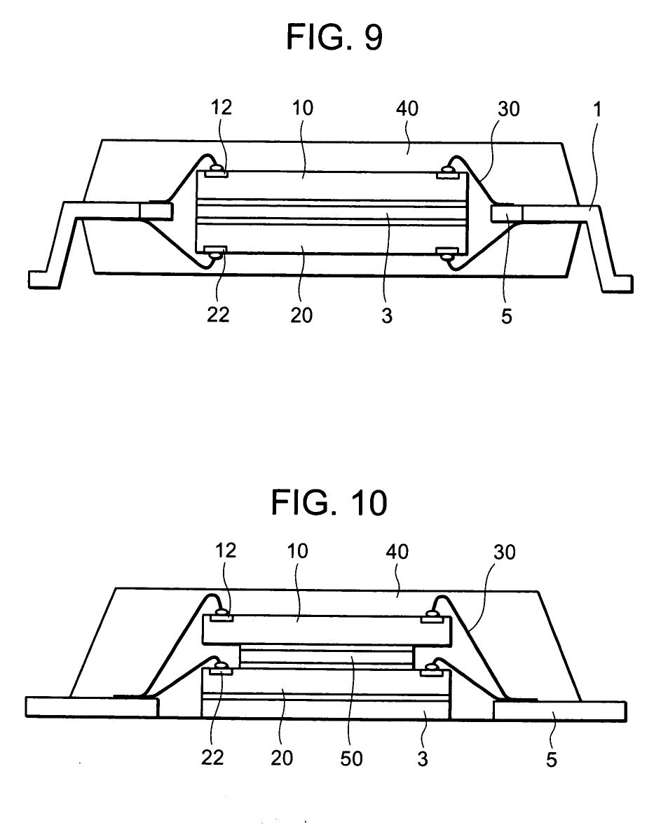

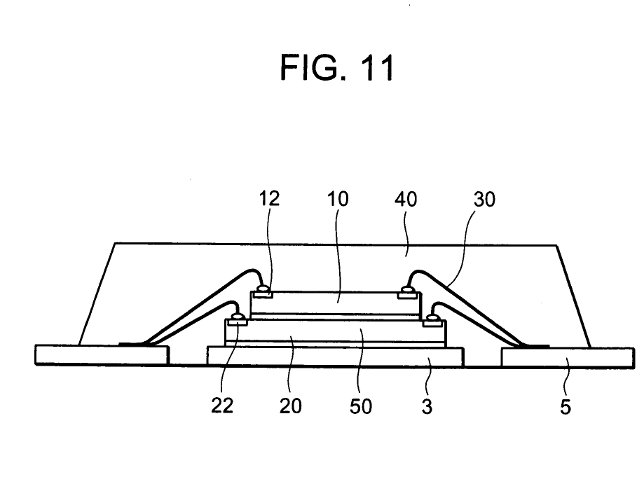

Next, a method of manufacturing the semiconductor device 100 according to this embodiment will be described with reference to FIGS. 2 to 8. FIGS. 2 to 7 are cross-sectional diagrams each showing a process for manufacturing the semiconductor device 100 according to this embodiment. FIGS. 8A and 8B are explanatory diagrams for comparing reverse bonding for the semiconductor device 100 according to this embodiment with normal bonding therefor.

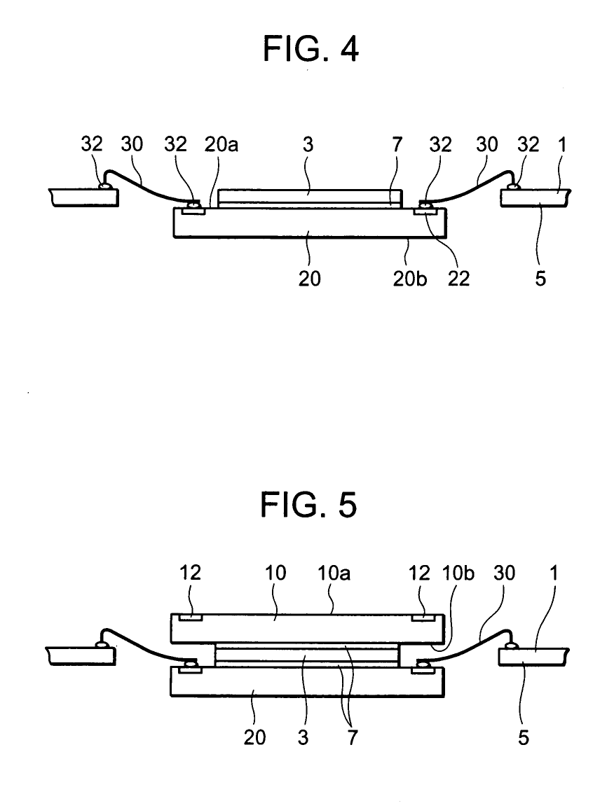

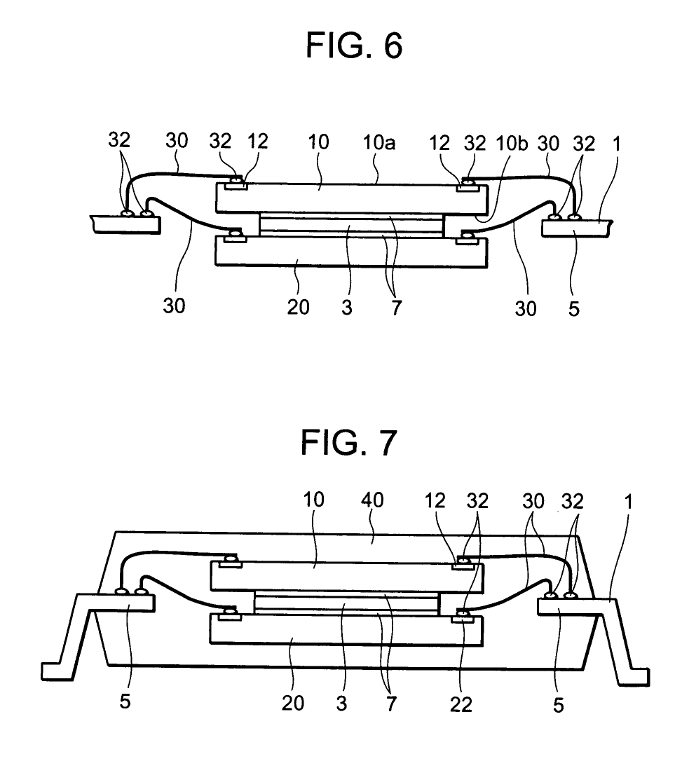

The method of manufacturing the semiconductor device 100 according to this embodiment includes the steps of: preparing the leadframe 1 having the island portion 3 and the plurality of leads 5 (FIG. 2); mounting the first semiconductor chip 20 having the top surface 20a provided with the plurality of electrode pads 22 on the periphery thereof, and the under surface 20b, with a side of the top surface 20a being opposed to the under surface 3b of the island portion 3 of the leadframe 1 (FIG. 3); mounting the second semiconductor chip 10 having the top surface 10a provided with the plurality of electrode pads 12 on the periphery thereof, and the under surface 10b, with a side of the under surface 10b being opposed to the top surface 3a of the island portion 3 of the leadframe 1 (FIG. 5); connecting wires 30 to each an associated one of the leads and associated one of the electrode pad by reverse bonding, with a point on each lead 5 of the plurality of leads 5 of the leadframe 1 being a starting point, and with the electrode pads 22 and 12 of the corresponding first semiconductor chip 20 and second semiconductor chip 10 being an ending point (FIGS. 4 and 6); and encapsulating the first semiconductor chip 20 and the second semiconductor chip 10 with the encapsulation resin 40 (FIG. 7). The wires 30 are connected such that each side surface of the wires 30 contacts each electrode pad substantially in parallel with each of the top surfaces 10a and 20a of the first semiconductor chip 20 and the second semiconductor chip 10.

Specifically, as shown in FIG. 2, the leadframe 1 is prepared as a preparation for an assembly of the semiconductor device 100. In the vicinity of the center of the leadframe 1, the island portion 3 is formed.

Next, as shown in FIG. 3, the first semiconductor chip 20 is mounted on the leadframe 1 by bonding the top surface 20a of the first semiconductor chip 20 to the under surface 3b of the island portion 3 of the leadframe 1 with an adhesive 7 for mounting. The leadframe 1 is fixed by using a jig (not shown), and the first semiconductor chip 20 is subjected to contact bonding from below by using a jig (not shown). At this time, the electrode pads 22 of the first semiconductor chip 20 are positioned to an outer side of the island portion 3 of the leadframe 1, and are disposed so that the electrode pads 22 and the island portion 3 do not overlap with each other.

Next, as shown in FIG. 4, the electrode pads 22 of the first semiconductor chip 20 corresponding to the leads 5 of the leadframe 1 are subjected to reverse wire bonding. The reverse bonding is disclosed in JP 11-097476 A (JP 2954109 B) filed by the applicant of this application. Specifically, a bump 32 serving as a golden ball is formed on the electrode pad 22 of the first semiconductor chip 20 by a bonder, the bump 32 serving as a golden ball is also formed on the corresponding lead 5. Then, reverse bonding is performed with a point on the lead 5 of the leadframe 1 being a starting point, and with each electrode pad 22 of the corresponding first semiconductor chip 20 being an ending point.

The wires 30 thus formed through reverse bonding are connected such that each side surface of the wires 30 contacts each electrode pad substantially in parallel with the top surface 20a of the first semiconductor chip 20. A loop height d1 of the wire 30 thus formed is reduced as shown in FIG. 8A. In a case of using the conventional normal bonding, as shown in FIG. 8B, the wire 30 rises and extends vertically from the electrode pad 22 of the first semiconductor chip 20, so a loop height d3 of the wire 30 is increased as compared to the loop height d1 of FIG. 8A.

In this embodiment, the loop height d1 of the wire 30 extending from the electrode pad 22 of the first semiconductor chip 20 is about less than 50 μm to 25 μm. In FIG. 4, the loop height d1 is 45 μm to 40 μm.

Next, as shown in FIG. 5, the second semiconductor chip 10 is mounted on the leadframe 1 by bonding the under surface 10b of the second semiconductor chip 10 to the top surface 3a of the island portion 3 of the leadframe 1 with the adhesive 7 for mounting. The second semiconductor chip 10 is mounted on the leadframe 1 from above by using a jig (not shown). At this time, the second semiconductor chip 10 is mounted at the center so that the wires 30 each connected to the first semiconductor chip 20 will not be in contact with the under surface 10b of the second semiconductor chip 10.

As shown in FIG. 8A, the loop height d1 of the wire 30 connected to the first semiconductor chip 20 is about less than 50 μm to 25 μm. Accordingly, when a distance d2 between the second semiconductor chip 10 and the first semiconductor chip 20 is about less than 80 μm to 25 μm of the thickness of the island portion 3, the wires 30 are not in contact with the under surface 10b of the second semiconductor chip 10. Therefore, it is unnecessary to provide a spacer 50 as shown in FIG. 8B.

Next, as shown in FIG. 6, the electrode pad 12 of the second semiconductor chip 10 corresponding to the lead 5 of the leadframe 1 is subjected to reverse bonding in the same manner as described above. Specifically, the bump 32 serving as a golden ball is formed on the electrode pad 12 of the second semiconductor chip 10 by a bonder, the bump 32 serving as a golden ball is also formed on the corresponding lead 5. Then, reverse bonding is performed with a point on the lead 5 of the leadframe 1 being a starting point, and the electrode pad 12 of the corresponding second semiconductor chip 10 being an ending point.

The loop height of the wire 30 thus formed by reverse bonding can be reduced as compared with the case of employing the conventional normal bonding, in the same manner as the loop height d1 of the first semiconductor chip 20.

Next, as shown in FIG. 7, the semiconductor chips are encapsulated with the plastic resin 40 by using a mold for encapsulating, to thereby obtain a predetermined shape. After that, the leads 5 are molded and made into a product. In this embodiment, it is unnecessary to provide the spacer, and the loop height of the wires 30 extending from the electrode pads 12 and 22 of the semiconductor chips 10 and 20 is also reduced. Accordingly, the distance between the second semiconductor chip 10 and the first semiconductor chip 20 is reduced, and the height of the mold for encapsulating can be reduced, which results in reduction in entire thickness of the semiconductor device 100.

As described above, according to the semiconductor device 100 of the embodiment of the present invention, and according to the method of manufacturing the same, by employment of reverse bonding, the height of the semiconductor device 100 can be reduced, thereby making it possible to mounting the plurality of semiconductor chips in compact on the leadframe. In addition, by eliminating the necessity of the spacer, the material costs for the spacer and the process for providing the spacer can be omitted, thereby reducing the manufacturing costs.

Further, in a conventional semiconductor device having a laminated structure, the semiconductor chip disposed above is formed with a shape smaller than that of the semiconductor chip disposed below so that the electrode pads of the lower semiconductor chip do not overlap the upper semiconductor chip. However, in the semiconductor device 100 according to this embodiment, it is unnecessary to form the upper semiconductor chip to be smaller than the lower semiconductor chip, and the second semiconductor chip 10 can be formed with the same shape as the first semiconductor chip 20. Further, irrespective of mounting the second semiconductor chip 10 and the first semiconductor chip 20 on both surfaces of the island portion 3 of the leadframe 1, it is possible to set directions in which the wires 30 are connected to the semiconductor chips to be the same directions. Accordingly, in the process for manufacturing the semiconductor device 100, it is unnecessary to place the second semiconductor chip 10 upside down to be bonded after the first semiconductor chip 20 is bonded to the leadframe 1, which simplifies the manufacturing process.

As described above, the embodiments of the present invention has been described with reference to the drawings. However, the embodiments are merely illustrative of the present invention, and various structures other than the above-mentioned structures can also be employed.

What is claimed is:

1. A method of manufacturing a semiconductor device, comprising:
mounting a first semiconductor chip having a top surface provided with a plurality of electrode pads on a periphery thereof, and an under surface provided on an opposite side of the top surface, with a side of the top surface being opposed to an under surface of a substance;
mounting a second semiconductor chip having a top surface provided with a plurality of electrode pads on a periphery thereof, and an under surface provided on an opposite side of the top surface, with a side of the under surface being opposed to a top surface of the substance; and
connecting wires to each an associated one of leads of a leadframe and an associated one of the electrode pads by reverse bonding, with a point on each lead of the plurality of leads being a starting point, and with each electrode pad of the first semiconductor chip being an ending point.

2. The method of manufacturing a semiconductor device according to claim 1, further comprising:
connecting wires to each an associated one of the leads and an associate done of the electrode pads by the reverse bonding, with a point on each lead of the plurality of leads being a starting point, and with each electrode pad of the second semiconductor chip being an ending point,

3. The method of manufacturing a semiconductor device according to claim 1, wherein the substance is an island portion of the leadframe.

4. A method of manufacturing a semiconductor device comprising:
preparing first and second semiconductor chips and a plurality of leads, each of the first and second semiconductor chips having a first main surface on which a plurality of electrode pads are formed and a second main surface;
connecting by use of a first wire each of the electrode pads of the first semiconductor chip to an associated one of the leads, the connecting of the first wire being performed by a reverse boding method in which each of the electrode pads of the first semiconductor chip and the associated one of the leads are made respectively as an ending point and a starting point of wiring boding; and
mounting the second semiconductor chip over the first semiconductor chip with an intervention of a spacer therebetween.

5. The method as claimed in claim 4, further comprising: connecting by use of a second first wire each of the electrode pads of the second semiconductor chip to an associated one of the leads, the connecting of the second wire being performed by a reverse boding method in which each of the electrode pads of the second semiconductor chip and the associated one of the leads are made respectively as an ending point and a starting point of wiring boding.

6. The method as claimed in claim 5, further comprising: encapsulating the first and second semiconductor chips, the spacer, the first and second wires and respective portions of the leads.

7. The method as claimed in claim 4, wherein said spacer is formed a part of a lead frame having the leads, said spacer being made of the same material as each of the leads.

8. The method as claimed in claim 4, wherein the spacer intervenes between the first main surface of the first semiconductor chip and the second main surface of the second semiconductor chip.

9. The method as claimed in claim 4, wherein each of the leads positions at a level that is higher than the first main surface of the first semiconductor chip.

10. The method as claimed in claim 9, wherein each of the leads positions at a level that is lower than the second main surface of the second semiconductor chip.
